(19) United States
(12) Patent Application Publication
(10) Pub. No.: US 2007/0218609 A1
(43) Pub. Date: Sep. 20, 2007

(54) Manufacturing method of semiconductor device

(75) Inventor: Tomohiko Tatsumi, Miyagi (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/705,764

(22) Filed: Feb. 14, 2007

(30) Foreign Application Priority Data
Mar. 14, 2006 (JP) 2006-069609

(51) Int. Cl. H01L 21/338

(52) U.S. Cl. 438/185; 257/E27.05

(57) ABSTRACT

A gate electrode is formed on a first conductivity type substrate. A second conductivity type implantation region is formed in the first conductivity type substrate. A first conductivity type implantation region is formed by implanting the first conductivity type impurities into the first conductivity type substrate to a depth deeper than the second conductivity type implantation region. An ISSG oxide film whose thickness ranges from 60 nm to 100 nm is formed to cover the first conductivity type substrate and the gate electrode. A silicone nitride film is formed on the ISSG oxide film. A second silicone oxide film is formed on the silicon nitride film. A sidewall is formed to cover the gate electrode and the first conductivity type substrate. A source/drain diffusion layer is formed by implanting second conductivity type impurities into the first conductivity type substrate.

### BACKGROUND OF THE INVENTION

This invention relates to a semiconductor device and a manufacturing method thereof, and particularly relates to a semiconductor device having a transistor element capable of writing two bits per cell and a manufacturing method thereof.

Conventionally, a thermal oxidation process is employed in the manufacturing process of a transistor element capable of writing two bits per cell. In particular, the thermal oxidation process is used to form oxide films (i.e., silicone oxide films) covering side surfaces of a gate electrode.

However, the thermal oxidation process necessities a long time heat treatment at high temperature, and therefore there is a possibility that impurities having been diffused in a diffusion layer in a previous step may further be diffused. Therefore, there is a possibility that impurity densities of respective transistor elements formed by the same process may vary from each other.

That is, electrical resistance of the diffusion layer of each of the transistor elements may fluctuate, and the decrease in the amount of hot electrons generated in the diffusion layer may occur. The decrease in the amount of hot electrons results in the insufficient accumulation of electrons, with the result that the writing and reading of two bits per cell may become impossible.

As a result, there is a possibility that the yield rate of the semiconductor device may decrease.

There is known a manufacturing method of a semiconductor device in which double sidewalls can be formed with an easy process.

This conventional manufacturing process of the semiconductor device includes steps of (a) forming a gate insulation film on a semiconductor substrate, (b) forming a gate electrode on the gate insulation film, (c) forming first sidewalls on side surfaces of the gate electrode, and (d) forming second sidewalls on the first sidewalls by causing the reaction of hydrogen gas and oxygen gas on the semiconductor substrate under a reduced pressure. Such a manufacturing process is disclosed in, for example, Japanese Laid-Open Patent Publication No. 2004-3490527.

However, in the forming process of the oxide film using the conventional thermal oxidation process, the impurities having been implanted in the substrate may be diffused outside a desired region due to the long time heat treatment as described above, so that there is a possibility that the transistor does not have desired electrical characteristics. Further, even if a thermally oxidized film (i.e., the second sidewalls) is formed using ISSG (In Situ Steam Generation) oxidation method as disclosed in the above described publication, the heat treatment time becomes longer in order to form the thermally oxidized film having the thickness of several tens of nanometer. In such a case, there is a possibility that the impurities having been implanted in the substrate may be diffused to reach an undesired region.

### SUMMARY OF THE INVENTION

An object of the present invention is to provide a manufacturing method of a semiconductor device capable of solving the above described problems.

The present invention provides a manufacturing method of the semiconductor device including the following steps.

First, a gate oxide film is formed on a first conductivity type substrate. A polysilicon film is formed on the gate oxide film. A tungsten silicide film is formed on the polysilicon film. A first silicon oxide film is formed on the tungsten silicide film. A resist mask having a pattern for forming a gate electrode is formed on the first silicon oxide film. A gate electrode including a gate oxide layer, a polysilicon layer, tungsten silicide layer and a first silicon oxide layer layered on the first conductivity type substrate is formed by patterning the gate oxide film, the polysilicon film, the tungsten silicide film and the first silicon oxide film using the resist mask as a mask. A second conductivity type (N-type) implantation region is formed by implanting second conductivity type impurities into the first conductivity type substrate exposed via the gate electrode using the gate electrode as a mask. A first conductivity type implantation region is formed by implanting first conductivity type impurities into a region including an overlapping region overlapping with the second conductivity type implantation region in plane in such a manner that the first conductivity type impurities are implanted in the thickness direction of the first conductivity type substrate to a depth deeper than the second conductivity type implantation region.

An ISSG oxide film having a thickness from 60 nm to 100 nm is formed on an entire exposed surfaces including a surface of the first conductivity type substrate, a side surface and a top surface of the gate electrode. A silicone nitride film is formed on the ISSG oxide film.

A second silicone oxide film is formed on the silicon nitride film. A sidewall including a layered body of an ISSG oxide layer, a silicon nitride layer and a second silicon oxide layer is formed by removing respective parts of the ISSG oxide film, the silicon nitride film and the second silicone oxide film. The sidewall covers the tungsten silicide layer, the polysilicon layer, the gate oxide layer and a part of the first conductivity type substrate in such a manner that a top surface and a part of a side surface of the gate electrode are exposed.

A source/drain diffusion layer is formed by implanting second conductivity type impurities into the first conductivity type substrate exposed via the gate electrode and the sidewall.

### BRIEF DESCRIPTION OF THE DRAWINGS

In the attached drawings:

FIG. 1 is a cross-sectional view schematically showing a semiconductor element according to the first embodiment of the present invention;

FIGS. 2A, 2B and 2C are cross-sectional views of the semiconductor element cut along a lengthwise direction of a gate, schematically showing a manufacturing process of the semiconductor element according to the first embodiment of the present invention;

FIGS. 3A, 3B and 3C are cross-sectional views schematically showing a manufacturing process following the manufacturing process shown in FIGS. 2A, 2B and 2C, and

FIG. 4 is a cross-sectional view schematically showing a semiconductor element according to the modification of the first embodiment of the present invention.

### DETAILED DESCRIPTION OF THE PREFERRED EMBODIMENT

An embodiment of the present invention will be described with reference to the attached drawings. Shapes, sizes and positions of respective components are schematically shown in the attached drawings merely for the illustrative purpose, but do not limit the scope of the present invention. Specific materials, conditions, numerical examples or the like described in the following description are merely preferred examples, but do not limit the scope of the present invention.

### First Embodiment

### <Configuration Example of Transistor>

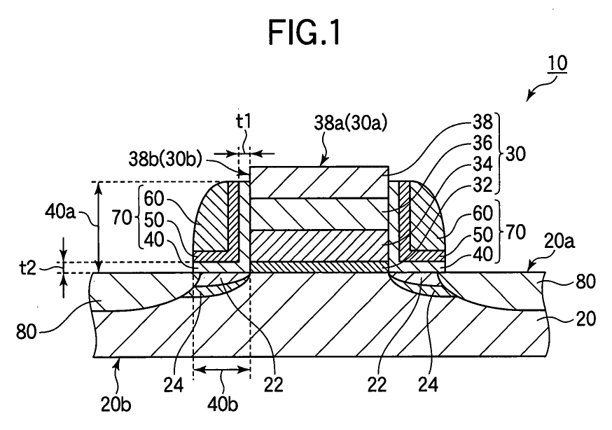

With reference to FIG. 1, a configuration example of a semiconductor element (i.e., a transistor) manufactured by a manufacturing method of a semiconductor device according to the present invention will be described. In this regard, the semiconductor element of the embodiment of the present invention is characterized by oxide films covering side surfaces of a gate electrode.

The transistor (the semiconductor element) and the manufacturing method thereof according to the embodiment of the present invention other than the structure and the manufacturing steps specifically described below (in this specification) are the same as those of the conventional transistor capable of wiring/reading two bits per cell.

FIG. 1 is a cross-sectional view schematically showing the semiconductor element according to the first embodiment of the present invention.

As shown in FIG. 1, the semiconductor device (the semiconductor element) 10 includes a first conductivity type substrate 20. In this example, the first conductivity type substrate 20 is a P-type substrate. The first conductivity type substrate 20 has a main (top) surface 20a and a back surface 20b opposing the main surface 20a.

A gate electrode 30 is formed on the first conductivity type substrate 20 (i.e., on the main surface 20a) and extends in a predetermined shape.

The gate electrode 30 has a top surface 30a substantially parallel to the main surface 20a and side surfaces 30b substantially perpendicular to the main surface 20a. The top surface 30a and the side surfaces 30b define the shape of the gate electrode 30.

The gate electrode 30 includes a gate oxide layer 32 formed on the main surface 20a, a polysilicon layer 34 formed on the gate oxide layer 32, a tungsten silicide layer 36 formed on the polysilicon layer 34, and a first silicon oxide layer 38 formed on the tungsten silicide layer 36. The gate oxide layer 32, the polysilicon layer 34, the tungsten silicide layer 36 and the first silicon oxide layer 38 are layered in this order, starting at the bottom.

Second conductivity type implantation regions 22 are formed in regions of the first conductivity type substrate 20. In this example, the second conductivity type implantation regions 22 are regions into which N-type impurities (for example, arsenic (As)) are implanted. The second conductivity type implantation regions 22 are so-called LDD (Lightly Doped Drain) regions.

The second conductivity type implantation regions 22 are formed by the impurities implanted outside the periphery (i.e., the side surfaces 30b) of the gate electrode 30, and second conductivity type implantation regions 22 are disposed in the regions outside the gate electrode 30 (i.e., disposed in the regions including the regions directly beneath sidewalls 70 described later).

First conductivity type implantation regions 24 are formed in the same regions as the second conductivity type implantation regions 22 in plane, as seen from the main surface 20a side of the first conductivity type substrate 20. Further, the first conductivity type implantation regions 24 are formed in the thickness direction of the first conductivity type substrate 20 to a depth deeper than the second conductivity type implantation regions 22.

The gate electrode 30 has sidewalls 70. In this example, each sidewall 70 includes an ISSG oxide layer 40, a silicon nitride layer 50 and a second silicon oxide layer 60 layered in this order, starting at the bottom.

The sidewalls 70 are formed to cover the tungsten silicide layer 36, the polysilicon layer 34, the gate oxide layer 32 and a part of the first conductivity type substrate 20 in such a manner that the top surface 30a and a part of each side surface 30b of the gate electrode 30 (i.e., a top surface 38a and a part of each side surface 38b of the first silicon oxide layer 38) are exposed.

The ISSG oxide layer 40 of each sidewall 70 covers from a part of the side surface 30b of the gate electrode 30 to the position above the second conductivity type implantation region 22.

The ISSG oxide layer 40 has a bent shape including a first partial region 40a covering the side surface 30b of the gate electrode 30 and a second partial region 40b covering the second conductivity implantation region 22 substantially perpendicular to the first partial region 40a.

The thickness t1 of the first partial region 40a covering the side surface 30b of the gate electrode 30 is substantially the same as the thickness t2 of the second partial region 40b covering the second conductivity type implantation region 22.

If the thicknesses t1 and t2 are too thick, the accumulation of electric charge may be inhibited. If the thickness t1 and t2 are too thin, electron may escape into the first conductivity type substrate 20 because of a tunnel effect.

The ISSG oxide layer 40 is an oxide film formed by ISSG oxidation method as described later.

According to the structure of the semiconductor element of the first embodiment of the present invention, the thickness t1 of the first partial region 40a and the thickness t2 of the second partial region 40b of each ISSG oxide layer 40 can be substantially the same as each other, and therefore electric charge can be stably accumulated in the silicon nitride layer 50. Therefore, the electric characteristics of the semiconductor element can be enhanced.

Each of the thicknesses t1 and t2 is preferably in the range from 60 nm to 100 nm.

The silicon nitride layer 50 is formed on the ISSG oxide layer 40. The silicon nitride layer 50 is a layer in which electric charge is accumulated during the operation of the transistor.

The second silicon oxide layer 60 is formed on the silicone nitride layer 50. The second silicone oxide layer 60 is a so-called NSG (Non Doped Silicate Glass) oxide layer.

The semiconductor element 10 includes source/drain diffusion layers 80. The source/drain diffusion layers 80 are formed in partial regions of the first conductivity type substrate 20 exposed via the gate electrode 30 and the sidewalls 70.

According to the structure of the semiconductor element of the first embodiment of the present invention, the thickness of each ISSG oxide layer 40 (that integrally covers from the side surface of the gate electrode 30 to the main surface 20a of the substrate 20) can be uniform and made thinner. Therefore, the characteristics of the transistor with regard to writing, storing and reading of data can be enhanced.

### <Manufacturing Method of Semiconductor Device>

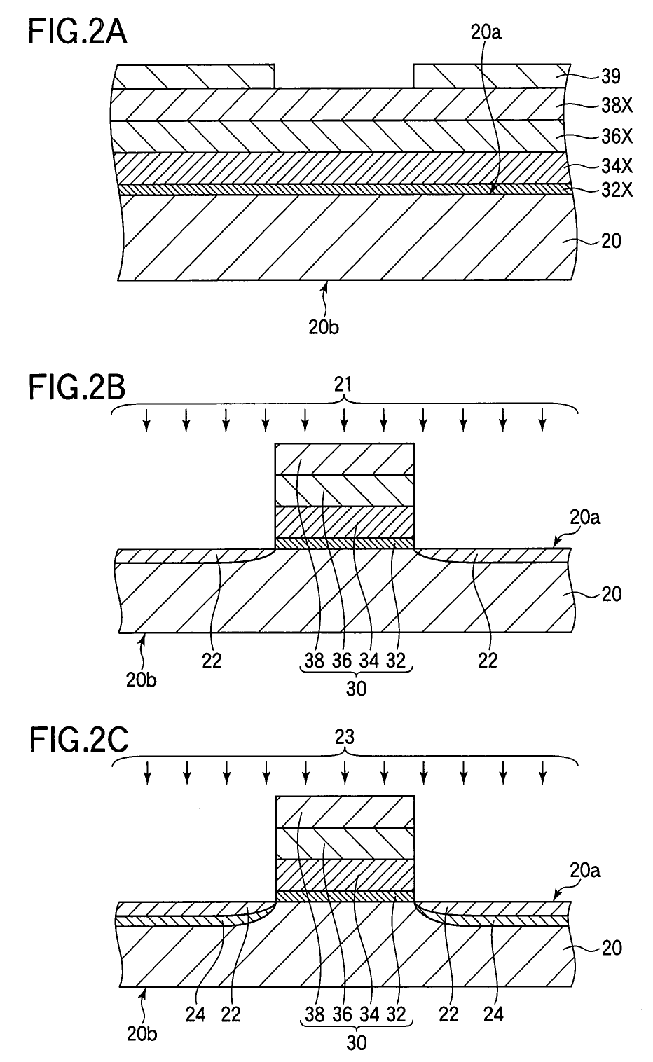

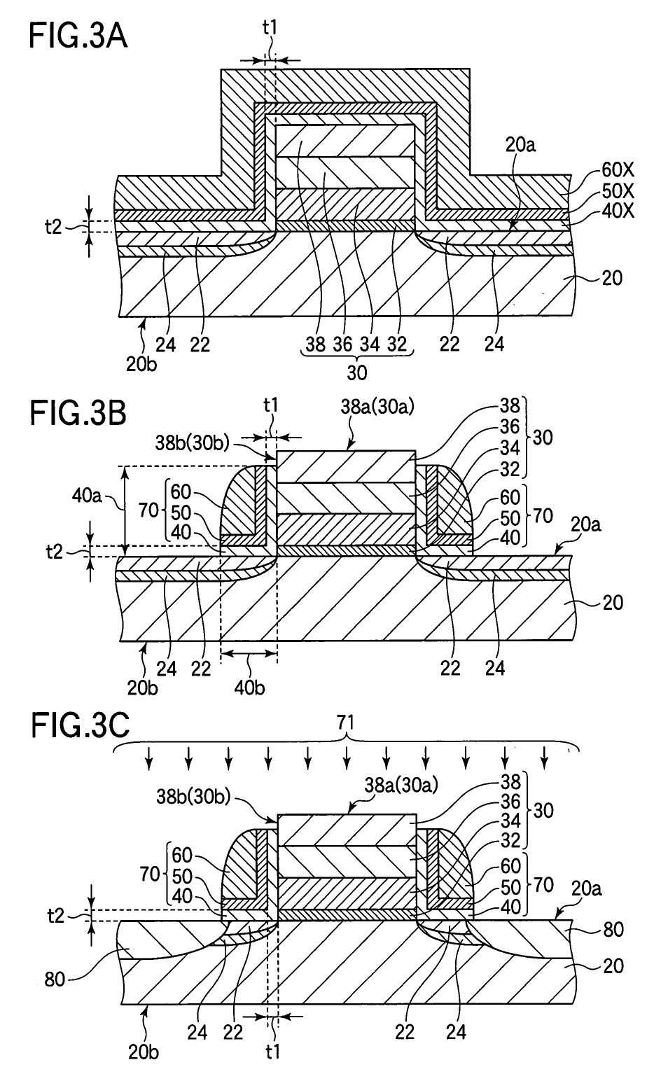

Hereinafter, the example of the manufacturing method of the semiconductor device (i.e., the transistor) of the present invention will be described with reference to FIGS. 2 and 3.

FIGS. 2A, 2B and 2C are cross-sectional views cut along the lengthwise direction of the gate, schematically showing respective steps of the manufacturing process of the semiconductor element of the first embodiment of the present invention.

FIGS. 3A, 3B and 3C are cross-sectional views schematically showing respective steps of the manufacturing process following the manufacturing process shown in FIGS. 2A, 2B and 2C.

First, as shown in FIG. 2A, the p-type (i.e., the first conductivity type) silicon substrate 20 is prepared.

Then, an element separation film (not shown) are formed on the main surface 20a of the p-type substrate 20 using, for example, LOCOS (Local Oxidation of Silicon) method.

Next, a gate oxide film 32X is formed on the main surface 20a of the P-type silicon substrate 20. The gate oxide film 32X can be formed using a conventional thermal oxidation process. The gate oxide film 32X can be formed of a conventional arbitrary and suitable material.

Then, a polysilicon film 34X is formed on the gate oxide film 32X using a conventional CVD process under an arbitrary and suitable condition.

Further, a tungsten silicide film 36X is formed on the polysilicon film 34X using the conventional CVD process under an arbitrary and suitable condition.

A first silicon oxide film 38X of an NSG oxide film is formed on the tungsten silicide film 36X using a conventional method.

Next, a resist mask 39 having a predetermined pattern for forming the gate electrode is formed on the first silicon oxide film 38X using a conventional photolithographic method.

Then, using the resist mask 39 as a mask, the layered body of the gate oxide film 32X, the polysilicon film 34X, the tungsten silicide film 36X and the first silicon oxide film 38X is patterned as shown in FIG. 2B.

With the patterning process, the gate electrode 30 is formed. The gate electrode 30 includes the gate oxide layer 32, the polysilicon layer 34, the tungsten silicide layer 36 and the first silicon oxide layer 38 which are layered on the P-type silicon substrate 20.

Next, using the gate electrode 30 as a mask, N-type (the second conductivity type) impurities 21 such as arsenic (As) are implanted into the p-type silicon substrate 20 exposed via the gate electrode 30, so that the N-type (the second conductivity type) implantation regions 22 are formed.

In the forming process of the N-type implantation regions 22, the dose amount of the N-type (the second conductivity type) impurities 21 is preferably in the range from, for example, 5×10¹² ions/cm² to 1.5×10¹³ ions/cm², and the implantation energy is preferably in the range from, for example, 20 KeV to 40 KeV.

Further, as shown in FIG. 2C, P-type (the first conductivity type) impurities 23 such as boron (B) are implanted into the regions of the P-type silicon substrate 20 which are the same regions as the N-type implantation regions 22 in plane. The implantation is performed in the thickness direction of the P-type silicon substrate 20 to a depth deeper than the N-type implantation regions 22, so that P-type (the first conductivity type) implantation regions 24 are formed.

In the forming process of the P-type implantation regions 24, the dose amount of the P-type (the first conductivity type) impurities 23 is preferably in the range from, for example, 5×10¹² ions/cm² to 1.5×10¹³ ions/cm², and the implantation energy is preferably in the range from, for example, 10 KeV to 30 KeV.

Alternatively, the forming process of the P-type implantation regions 22 can be performed prior to the forming process of the N-type implantation regions 24.

Next, as shown in FIG. 3A, an ISSG oxide film 40X is formed on the entire exposed surfaces including the main surface 20a of the P-type silicon substrate 20, the side surface 30b and the top surface 30a of the gate electrode 30 using the ISSG oxidation method.

By forming the ISSG oxide film 40X using the ISSG oxidation method, the thickness t1 of the first partial region 40a covering the side surfaces 30b of the gate electrode 30 and the thickness t2 of the second partial region 40b covering the second conductivity type (N-type) implantation regions 22 can be substantially the same as each other. In other words, the ISSG oxide layer 40 can be formed to have a substantially uniform thickness (see FIG. 3B).

Here, the ISSG oxidation method will be briefly described.

The ISSG oxidation method is a method for forming an oxide film. In the ISSG oxidation method, oxygen (O₂) gas is heated instantaneously to a high temperature by means of a lamp as a heat source, and the heated oxygen gas is fed into a chamber whose inner pressure is lower than air pressure. Oxidation process is performed in the chamber of high oxygen partial pressure, so that the heat treatment time can be reduced.

To be more specific, the oxide film can be formed under the condition that the internal temperature of the chamber (in which the P-type silicon substrate 20 is placed) is in the range from 900° C. to 1200° C., the oxygen partial pressure in the chamber is in the range from 1066 Pa to 1200 Pa (from 8 Torr to 9 Torr), and the heat treatment time is in the range from 30 seconds to 60 seconds. In this regard, the oxygen partial pressure is substantially the same as the internal pressure in the chamber.

The thickness of the ISSG oxide film 40X is preferably in the range from 60 nm to 100 nm, in consideration of the accumulation and storage of electric charge in the silicon nitride film described later.

With such a process, the oxide film (the ISSG oxide film 40X) can be formed by a heat treatment of a very short time. Therefore, it becomes possible to prevent the diffusion of the impurities to an undesired region that may otherwise be caused by a long time heat treatment for forming the oxide film. As a result, the electric characteristics of the manufactured semiconductor element can be stabilized and enhanced.

Moreover, the thickness of the ISSG oxide film 40X can be entirely uniform. In particular, the thickness t1 of the first partial region 40a covering the side surfaces 30b of the gate electrode 30 and the thickness t2 of the second partial region 40b covering the N-type implantation regions 22 can be entirely uniform. Therefore, the electric characteristics of the manufactured semiconductor element and the yield rate can be further enhanced.

Next, a silicone nitride film 50X is formed on the entire surface of the ISSG oxide film 40X using, for example, a plasma CVD method at the temperature in the range from 700° C. to 800° C. The thickness of the silicon nitride film 50X is substantially in the range from 5 nm to 10 nm.

Then, a second silicon oxide film 60X is formed on the silicon nitride film 50X. The second silicon oxide film 60X is an NSG oxide film formed using, for example, the plasma CVD method as described above. The thickness of the NSG oxide film can be substantially in the range from 25 nm to 50 nm.

Further, an etching process is performed on the layered body of the ISSG oxide film 40X, the silicon nitride film 50X and the second silicon oxide film 60X using a conventional etching process (i.e., a sidewall etching process), so that the sidewalls 70 are formed.

As the sidewall etching process, it is possible to perform, for example, a dry etching process using a mixed gas of CF₄, CHF₃ and Ar as gas composition.

With the etching process, a part of the layered body is removed so that the entire surface of the top surface 30a of the gate electrode 30 (i.e., the top surface 38a of the first silicon oxide film 38) and a part of the side surfaces 30b of the gate electrode 30 (i.e., the side surfaces 38b of the first silicone oxide film 38) are exposed.

With this process, as shown in FIG. 3B, the sidewalls 70 are formed to cover the tungsten silicide layer 36, the polysilicon layer 34, the gate oxide layer 32 and a part of the P-type silicon substrate 20 in such a manner that a part of the side surfaces 38b of the first silicon oxide film 38 are exposed.

Next, as shown in FIG. 3C, N-type (second conductivity type) impurities 71 are implanted into the P-type (first conductivity type) silicon substrate 20 exposed via the gate electrode 30 and the sidewalls 70, so that the source/drain diffusion layers 80 are formed.

In the forming process of the source/drain diffusion layers 80, the dose amount of the N-type impurities 71 is preferably in the range from, for example, 5×10¹⁴ ions/cm² to 1.5×10¹⁵ ions/cm², and the implantation energy is preferably in the range from, for example, 20 KeV to 50 KeV.

### <Operation of Semiconductor Element>

The operation of the semiconductor element (i.e., the transistor) according to the embodiment of the present invention will be briefly described with reference to FIG. 1.

When the source/drain diffusion layers 80 and the gate electrodes 30 are applied with suitable electric potentials, electrons of high energy (called as hot electrons) are generated in the second conductivity type (N-type) implantation region 22 of the drain side. The hot electrons jump over the ISSG oxide film 40 of the drain side, and are accumulated in the silicon nitride layer 50 of the drain side.

With this, positive holes are generated in the second conductivity type (N-type) implantation region 22 beneath the silicon nitride layer 50 in which the hot electrons are accumulated, and therefore the electric resistance of the second conductivity type implantation region 22 increases. Accordingly, when the second conductivity type (N-type) implantation region 22 side with the increased electric resistance is the source side, the electric current flow is remarkably reduced. The data detection is carried out by detecting the difference in electric current.

### Modification of First Embodiment

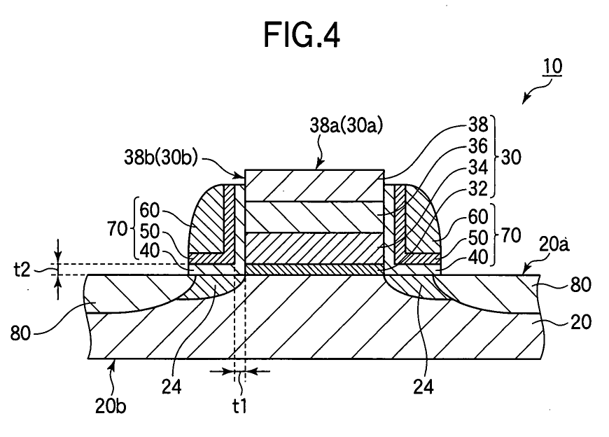

Hereinafter, a modification of the first embodiment of the present invention will be described with reference to FIG. 4.

FIG. 4 is a cross-sectional view schematically showing the semiconductor element according to the modification of the first embodiment of the present invention.

The semiconductor element (transistor) 10 is characterized in that the first conductivity type (P-type) implantation regions 24 are provided beneath the silicon nitride layer 50. Elements other than the first conductivity type implantation regions 24 and the manufacturing method thereof are the same as those described in the first embodiment, and therefore duplicate explanation will be omitted.

In this example, the first conductivity type implantation regions 24 of the semiconductor element 10 are of P-type. The first conductivity type implantation regions 24 are formed by implanting the impurities into regions outside the periphery (i.e., the side surfaces 30b) of the gate electrode 30, and the first conductivity type implantation regions 24 are disposed outside the gate electrode 30 (i.e., disposed in regions including the regions directly beneath the sidewalls 70).

The fist conductivity type implantation regions 24 are characterized by the density of the implanted impurities.

In the forming process of the first conductivity type implantation regions 24, the dose amount of the P-type (i.e., the first conductivity type) impurities is preferably in the range from 5×10¹² ions/cm² to 1.5×10¹³ ions/cm². The implantation energy is in the range from 10 KeV to 30 KeV.

In this example, the second conductivity type implantation regions 22 (as was described in the first embodiment) are not formed. However, it is also possible to form the second conductivity type implantation regions 22 under the condition that the dose amount of the N-type (the second conductivity type) impurities is preferably in the range from, for example, 5×10¹¹ ions/cm² to 1.0×10¹³ ions/cm². In this case, the density of the impurities in the second conductivity type implantation regions 22 is substantially in the range from 5×10¹⁶ ions/cm³ to 5×10¹⁷ ions/cm³, and the density of the impurities in the first conductivity type implantation regions 24 is substantially in the range from 1.0×10¹⁶ ions/cm³ to 5×10¹⁶ ions/cm³.

With such a structure, it is possible to obtain the same advantages described in the first embodiment.

According to the first embodiment of the present invention and the modification thereof, the heat treatment is completed in a short time due to the ISSG oxidation method, and therefore it becomes possible to prevent the implanted impurities from being diffused and reaching to a desired region. Further, the thermally oxidized film formed by the thermal oxidation process of the ISSG method has the uniform thickness on the surface of the substrate and on the side surface of the gate electrode. Therefore, the electric characteristics of the manufactured transistor can be uniform. Accordingly, the accuracy in wiring and reading of the transistor (semiconductor element) can be enhanced. Moreover, the yield rate of the manufactured transistor can be enhanced.

According to the present invention, there is provided a semiconductor device comprising:

a first conductivity type substrate,

a gate electrode including a gate oxide layer formed on the first conductivity type substrate, a polysilicon layer formed on the gate oxide layer, a tungsten silicide layer formed on the polysilicon layer, and a first silicon oxide layer formed on the tungsten silicide layer;

a second conductivity type implantation region formed in a region of the first conductivity type substrate including an outer region of a region directly beneath the gate electrode;

a first conductivity type implantation region formed in a region including an overlapping region overlapping with the second conductivity type implantation region in plane, the first conductivity type implantation region being formed in the thickness direction of the first conductivity type substrate to a depth deeper than the second conductivity type implantation region;

a sidewall including a layered body of an ISSG oxide layer, a silicon nitride layer and a second silicon oxide layer, the sidewall covering the tungsten silicide layer, the polysilicon layer, the gate oxide layer and a part of the first conductivity type substrate in such a manner that a top surface and a part of a side surface of the gate electrode are exposed, and

a source/drain diffusion layer formed in the first conductivity type substrate exposed via the gate electrode and the sidewall.

According to another aspect of the present invention, there is provided a semiconductor device comprising:

a first conductivity type substrate,

a gate electrode including a gate oxide layer formed on the first conductivity type substrate, a polysilicon layer formed on the gate oxide layer, a tungsten silicide layer formed on the polysilicon layer, and a first silicon oxide layer formed on the tungsten silicide layer;

a first conductivity type implantation region formed in a region of the first conductivity type substrate including an outer region of a region directly beneath the gate electrode;

a sidewall including a layered body of an ISSG oxide layer, a silicon nitride layer and a second silicon oxide layer, the sidewall covering the tungsten silicide layer, the polysilicon layer, the gate oxide layer and a part of the first conductivity type substrate in such a manner that a top surface and a part of a side surface of the gate electrode are exposed, and

a source/drain diffusion layer formed in the first conductivity type substrate exposed via the gate electrode and the sidewall.

More specifically, the ISSG oxide layer includes a first partial region extending so as to face a side surface of the gate electrode and a second partial region extending so as to face a surface of the substrate.

Additionally, the first conductivity type substrate is a P-type substrate, the second conductivity type impurities are N-type impurities, and the first conductivity type impurities are P-type impurities.

While the preferred embodiments of the present invention have been illustrated in detail, it should be apparent that modifications and improvements may be made to the invention without departing from the spirit and scope of the invention as described in the following claims.

What is claimed is:

1. A manufacturing method of a semiconductor device, said manufacturing method comprising:
forming a gate oxide film on a first conductivity type substrate;
forming a polysilicon film on said gate oxide film;
forming a tungsten silicide film on said polysilicon film;
forming a first silicon oxide film on said tungsten silicide film;
forming a resist mask having a pattern for forming a gate electrode on said first silicon oxide film;
forming a gate electrode including a gate oxide layer, a polysilicon layer, tungsten silicide layer and a first silicon oxide layer layered on said first conductivity type substrate by patterning said gate oxide film, said polysilicon film, said tungsten silicide film and said first silicon oxide film using said resist mask as a mask;
forming a second conductivity type implantation region by implanting second conductivity type impurities into said first conductivity type substrate exposed via said gate electrode using said gate electrode as a mask;
forming a first conductivity type implantation region by implanting first conductivity type impurities into a region including an overlapping region overlapping with said second conductivity type implantation region in plane in such a manner that said first conductivity type impurities are implanted in the thickness direction of said first conductivity type substrate to a depth deeper than said second conductivity type implantation region;
forming an ISSG oxide film having a thickness from 60 nm to 100 nm on an entire exposed surfaces including a surface of said first conductivity type substrate, a side surface and a top surface of said gate electrode;
forming a silicone nitride film on said ISSG oxide film;
forming a second silicone oxide film on said silicon nitride film;
forming a sidewall including a layered body of an ISSG oxide layer, a silicon nitride layer and a second silicon oxide layer, by removing respective parts of said ISSG oxide film, said silicon nitride film and said second silicone oxide film, said sidewall covering said tungsten silicide layer, said polysilicon layer, said gate oxide layer and said first conductivity type substrate in such a manner that a top surface and a part of a side surface of said gate electrode are exposed, and
forming a source/drain diffusion layer by implanting second conductivity type impurities into said first conductivity type substrate exposed via said gate electrode and said sidewall.

2. The manufacturing method according to claim 1, wherein said forming method of said ISSG film includes a heat treatment under the atmosphere of oxygen with the partial pressure ranging from 1066 Pa nm to 1200 Pa, at the temperature ranging from 900° C. to 1200° C., and the heating time ranging from 30 seconds to 60 seconds.

3. The manufacturing method according to claim 1, wherein said forming process of a second conductivity type implantation region is performed under the condition that the dose amount of said second conductivity type impurities ranges from 5×10¹² ions/cm² to 1.5×10¹³ ions/cm², and the implantation energy ranges from 20 KeV to 40 KeV, and
wherein said forming process of a first conductivity type implantation region is performed under the condition that the dose amount of said first conductivity type impurities ranges from 5×10¹² ions/cm² to 1.5×10¹³ ions/cm², and the implantation energy ranges from 10 KeV to 30 KeV.

4. The manufacturing method according to claim 1, wherein said first conductivity type substrate is a P-type substrate, said second conductivity type impurities are N-type impurities, and said first conductivity type impurities are P-type impurities.

5. A manufacturing method of a semiconductor device, said manufacturing method comprising:
forming a gate oxide film on a first conductivity type substrate;
forming a polysilicon film on said gate oxide film;
forming a tungsten silicide film on said polysilicon film;
forming a first silicon oxide film on said tungsten silicide film;
forming a resist mask having a pattern for forming a gate electrode on said first silicon oxide film;
forming a gate electrode including a gate oxide layer, a polysilicon layer, tungsten silicide layer and a first silicon oxide layer layered on said first conductivity type substrate by patterning said gate oxide film, said polysilicon film, said tungsten silicide film and said first silicon oxide film using said resist mask as a mask;
forming a first conductivity type implantation region by implanting first conductivity type impurities into said first conductivity type substrate exposed via said gate electrode using said gate electrode as a mask, under the condition that the dose amount of said first conductivity type impurities ranges from 5×10¹² ions/cm² to 1.0×10¹³ ions/cm², and the implantation energy ranges from 10 KeV to 30 KeV.
forming an ISSG oxide film on entire exposed surfaces of said first conductivity type substrate and said gate electrode;
forming a silicone nitride film on said ISSG oxide film;
forming a second silicone oxide film on said silicon nitride film;
forming a sidewall including a layered body of an ISSG oxide layer, a silicon nitride layer and a second silicon oxide layer, by removing respective parts of said ISSG oxide film, said silicon nitride film and said second silicone oxide film, said sidewall covering said tungsten silicide layer, said polysilicon layer, said gate oxide layer and a part of said first conductivity type substrate in such a manner that a top surface and a part of a side surface of said gate electrode are exposed, and
forming a source/drain diffusion layer by implanting second conductivity type impurities into said first conductivity type substrate exposed via said gate electrode and said sidewall.

6. The manufacturing method according to claim 5, wherein said first conductivity type substrate is a P-type substrate, said second conductivity type impurities are N-type impurities, and said first conductivity type impurities are P-type impurities.
